(19) United States
(12) Patent Application Publication
(10) Pub. No.: US 2026/0354237 A1
(43) Pub. Date: Nov. 5, 2026

(54) COMPOSITE SUBSTRATE AND METHOD OF MANUFACTURING COMPOSITE SUBSTRATE

(71) Applicant: NGK Corporation, Nagoya-shi (JP)

(72) Inventors: Takeshi YAMAMOTO, Nagoya-shi (JP); Junji SAKAI, Nagoya-shi (JP); Tomoyoshi TAI, Nagoya-shi (JP)

(21) Appl. No.: 19/718,181

(22) Filed: Jun. 24, 2026

Related U.S. Application Data
(63) Continuation of application No. PCT/JP2024/041494, filed on Nov. 22, 2024.

(30) Foreign Application Priority Data
Dec. 25, 2023 (JP) 2023-218694

(51) Int. Cl. H10W 70/685; H10W 70/05

(52) U.S. Cl. CPC H10W 70/686; H10W 70/05

(57) ABSTRACT

A composite substrate includes: a functional substrate made of a functional material; and a support substrate made of a semiconductor material and bonded to the functional substrate to support the functional substrate, wherein the functional substrate includes a first layer and a second layer arranged closer to the support substrate than the first layer and made of an amorphous substance containing a noble gas, and the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material.

### CROSS-REFERENCE TO RELATED APPLICATION

This application is a continuation application of PCT/JP2024/041494 filed on Nov. 22, 2024, which claims the benefit of priority of Japanese Patent Application No. JP2023-218694 filed on Dec. 25, 2023 the entire contents of which are incorporated herein by reference.

### 1. TECHNICAL FIELD

The present invention relates to a composite substrate and a method of manufacturing the composite substrate.

### 2. DESCRIPTION OF RELATED ART

Conventionally known is a composite substrate for use in a surface acoustic wave device or the like, the composite substrate being formed by bonding a functional substrate made of a piezoelectric material such as LN (LiNbO₃: lithium niobate) or LT (LiTaO₃: lithium tantalate) and a support substrate made of a semiconductor material such as Si. As a method of fabricating such a composite substrate, there has been known a method of irradiating each of bonding surfaces of a functional substrate and a support substrate with a fast atom beam (FAB) to perform activation treatment, and then directly bonding the bonding surfaces to each other. However, there has been a problem in that this method will provide a low bonding strength between the substrates and separation in a processing step may occur after the bonding.

Thus, as a technique for solving the problem, the technique of Patent Literature 1 (Japanese Patent No. 7152711) is known. Patent Literature 1 discloses a method of manufacturing a composite substrate by irradiating a support substrate with a fast atom beam to sputter a semiconductor material of the support substrate so that a bonding layer made of an amorphous semiconductor material obtained by making the semiconductor material amorphous is formed on a piezoelectric substrate, and performing pressure welding on the piezoelectric substrate and the support substrate with the bonding layer therebetween. This method increases the bonding strength between the piezoelectric substrate and the support substrate, preventing separation after the bonding.

In a composite substrate in which a functional substrate such as a piezoelectric substrate and a support substrate are bonded to each other, a sputtering time is preferably as short as possible in terms of productivity; when the sputtering time is reduced, the thickness of the bonding layer is decreased as a result. On the contrary, in order to achieve a desired bonding strength in a conventional bonding method as described in Patent Literature 1, it is necessary that the bonding layer have a certain thickness.

The present invention has been made in view of the above, and a main object thereof is to provide a composite substrate and a method of manufacturing the composite substrate that are capable of achieving a sufficient bonding strength even when a bonding layer has a small thickness in a composite substrate in which a functional substrate and a support substrate are bonded to each other with the bonding layer therebetween.

### SUMMARY OF THE INVENTION

A composite substrate according to the 1st aspect of the present invention includes: a functional substrate made of a functional material; and a support substrate made of a semiconductor material and bonded to the functional substrate to support the functional substrate, wherein the functional substrate includes a first layer and a second layer arranged closer to the support substrate than the first layer and made of an amorphous substance containing a noble gas, and the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material.

According to the 2nd aspect of the present invention, in the composite substrate of the 1st aspect, the functional substrate may include: a first functional layer that is made of a crystalline substance of the functional material; and a second functional layer that includes an amorphous substance of the functional material and is in contact with the bonding layer, the first layer may be the first functional layer, and the second layer may be the second functional layer.

According to the 3rd aspect of the present invention, in the composite substrate of the 1st aspect, the functional substrate may be bonded to the support substrate with an insulation layer therebetween, the insulation layer being made of an insulating material, the insulation layer may include: a first insulation layer made of the insulating material; and a second insulation layer that includes an amorphous substance of the insulating material and is in contact with the bonding layer, the first layer may be the first insulation layer, and the second layer may be the second insulation layer.

According to the 4th aspect of the present invention, in the composite substrate of the 2nd or 3rd aspect, the bonding layer may have a thickness of 0.3 nm or more and 3 nm or less.

According to the 5th aspect of the present invention, in the composite substrate of the 2nd or 3rd aspect, the bonding layer may contain the noble gas, and a content of the noble gas in the bonding layer may be lower than a content of the noble gas in the second support layer.

According to the 6th aspect of the present invention, in the composite substrate of the 2nd or 3rd aspect, the bonding layer may contain a metal element.

According to the 7th aspect of the present invention, in the composite substrate of the 2nd aspect, the first functional layer may contain the noble gas or may not contain the noble gas, and a content of the noble gas in the first functional layer when the first functional layer contains the noble gas may be lower than a content of the noble gas in the second functional layer.

According to the 8th aspect of the present invention, in the composite substrate of the 7th aspect, the content of the noble gas in the second functional layer may be lower than a content of the noble gas in the second support layer.

According to the 9th aspect of the present invention, in the composite substrate of the 3rd aspect, the first insulation layer may contain the noble gas or may not contain the noble gas, and a content of the noble gas in the first insulation layer when the first insulation layer contains the noble gas may be lower than a content of the noble gas in the second insulation layer.

According to the 10th aspect of the present invention, in the composite substrate of the 9th aspect, the content of the noble gas in the second insulation layer may be lower than a content of the noble gas in the second support layer.

According to the 11th aspect of the present invention, in the composite substrate of the 2nd or 3rd aspect, the first support layer may contain the noble gas or may not contain the noble gas, and a content of the noble gas in the first support layer when the first support layer contains the noble gas may be lower than a content of the noble gas in the second support layer.

A method of manufacturing a composite substrate according to the 12th aspect of the present invention, the composite substrate including a functional substrate made of a functional material and a support substrate including a semiconductor material and supporting the functional substrate, the method includes: an activation step of performing irradiation with a fast atom beam on each of a surface of the functional substrate and a surface of a semiconductor substrate made of the semiconductor material so that at least portions of times for respectively irradiating the surfaces overlap with each other; a sputtering step of sputtering the semiconductor material onto the surface of the functional substrate by continuing the irradiation of the surface of the semiconductor substrate with the fast atom beam after stopping the irradiation of the surface of the functional substrate with the fast atom beam, the sputtering step being performed subsequent to the activation step; and a bonding step of bonding the functional substrate, on which the semiconductor material is sputtered in the sputtering step, and the semiconductor substrate to each other to obtain a bonded body.

A method of manufacturing a composite substrate according to the 13th aspect of the present invention, the composite substrate including a functional substrate made of a functional material and a support substrate including a semiconductor material and supporting the functional substrate, the method includes: an insulation layer formation step of forming, on a surface of the functional substrate, an insulation layer made of an insulating material; an activation step of performing irradiation with a fast atom beam on each of a surface of the insulation layer and a surface of a semiconductor substrate made of the semiconductor material so that at least portions of times for respectively irradiating the surfaces overlap with each other; a sputtering step of sputtering the semiconductor material onto the surface of the insulation layer by continuing the irradiation of the surface of the semiconductor substrate with the fast atom beam after stopping the irradiation of the surface of the insulation layer with the fast atom beam, the sputtering step being performed subsequent to the activation step; and a bonding step of bonding the functional substrate and the semiconductor substrate to each other with the insulation layer, on which the semiconductor material is sputtered in the sputtering step, therebetween to obtain a bonded body.

According to the 14th aspect of the present invention, in the method of manufacturing the composite substrate of the 12th or 13th aspect, in the sputtering step, a sputter film made of an amorphous substance of the sputtered semiconductor material may be formed with a thickness of 0.3 nm or more and 3 nm or less on the surface of the functional substrate or the insulation layer.

According to the 15th aspect of the present invention, in the method of manufacturing the composite substrate of the 12th or 13th aspect, the functional substrate and the semiconductor substrate may be arranged in a vacuum chamber in which a first fast atom beam gun and a second fast atom beam gun are placed, in the activation step, a noble gas may be supplied to each of the first fast atom beam gun and the second fast atom beam gun, the surface of the functional substrate or the insulation layer may be irradiated with the fast atom beam using the noble gas from the first fast atom beam gun, and further, the surface of the semiconductor substrate may be irradiated with the fast atom beam using the noble gas from the second fast atom beam gun, and, in the sputtering step, the irradiation with the fast atom beam from the first fast atom beam gun toward the surface of the functional substrate or the insulation layer may be stopped while the noble gas is kept supplied to the first fast atom beam gun.

According to the 16th aspect of the present invention, in the method of manufacturing the composite substrate of the 15th aspect, in the activation step, the irradiation with the fast atom beam from the first fast atom beam gun toward the surface of the functional substrate or the insulation layer and the irradiation with the fast atom beam from the second fast atom beam gun toward the surface of the semiconductor substrate may be concurrently performed.

According to the present invention, it is possible to provide a composite substrate and a method of manufacturing the composite substrate that are capable of achieving a sufficient bonding strength even when a bonding layer has a small thickness in a composite substrate in which a functional substrate and a support substrate are bonded to each other with the bonding layer therebetween.

### BRIEF DESCRIPTION OF THE DRAWINGS

FIG. 1 is a schematic cross-sectional view showing a schematic configuration of a composite substrate according to a first embodiment of the present invention.

FIGS. 2A, 2B, 2C, 3A, 3B and 3C illustrate one example of a process of manufacturing a composite substrate according to the first embodiment of the present invention.

FIG. 4 is a schematic cross-sectional view showing a schematic configuration of a composite substrate according to a second embodiment of the present invention.

FIGS. 5A, 5B, 5C, 5D, 6A, 6B and 6C illustrate one example of a process of manufacturing a composite substrate according to the second embodiment of the present invention.

FIG. 7 is a schematic cross-sectional view showing a schematic configuration of a composite substrate according to a third embodiment of the present invention.

FIG. 8 is a schematic cross-sectional view showing a schematic configuration of a composite substrate according to a fourth embodiment of the present invention.

FIGS. 9A and 9B show observation photographs of Example 1 and a comparison example respectively.

FIGS. 10A and 10B show tables illustrating the EDX analysis results of Examples 1 and 3 respectively.

FIG. 11 shows a table illustrating the relation between FAB irradiation time, a bonding layer thickness, and a bonding strength in a composite substrate.

FIG. 12 shows a table illustrating the relation between FAB irradiation time for a functional substrate and a semiconductor substrate and a bonding strength in a composite substrate.

### DESCRIPTION OF PREFERRED EMBODIMENTS

Embodiments of the present invention will be described below with reference to the drawings. However, the present invention is not limited to these embodiments. In addition, the drawings may be schematically illustrated in terms of, for example, the width, thickness, and shape of each portion as compared with the embodiments for further clarifying the description. However, the drawings are merely examples and do not limit the interpretation of the present invention.

### First Embodiment

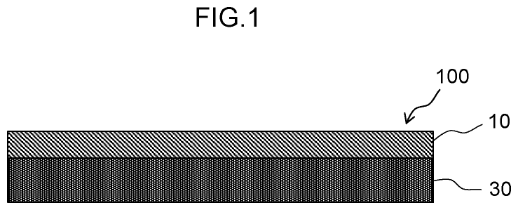

FIG. 1 is a schematic cross-sectional view showing a schematic configuration of a composite substrate according to a first embodiment of the present invention. A composite substrate 100 according to the present embodiment is to be used for a variety of uses such as optical elements forming optical waveguides, piezoelectric elements forming surface acoustic wave (SAW) filters, and semiconductor elements of various kinds, and has a structure in which a functional substrate 10 made of a functional material such as a piezoelectric material or a semiconductor material is bonded to a support substrate 30.

As a material of the functional substrate 10, for example, a piezoelectric material such as LN (LiNbO₃: lithium niobate), LT (LiTaO₃: lithium tantalate), crystal, AlN (aluminum nitride), or PZT (Pb(Zr, Ti)O₃: lead zirconate titanate) is used. Note that the material of the functional substrate 10 can be selected randomly in accordance with a use of the composite substrate 100, and the functional substrate 10 may include, for example, a semiconductor material such as SiC, InP, GaN, GaP, or diamond, a material having an electro-optic effect such as lithium niobate-lithium tantalate or KTP (potassium titanyl phosphate), quartz, or glass in place of the piezoelectric material. It is possible to use the functional substrate 10 made of any of a variety of functional materials other than these, in accordance with a use of the composite substrate 100.

The support substrate 30 supports the functional substrate 10. As the support substrate 30, any appropriate substrate can be used. The support substrate 30 may include a single crystalline substance or may include a polycrystalline substance. The functional substrate 10 and the support substrate 30 are directly bonded to each other.

As a material included in the support substrate 30, a semiconductor material such as Si, Ge, SiC, InP, GaN, or a sapphire can be used. Alternatively, Si(1-x)Ox (where 0.008≤x≤0.408), SOI (Silicon on Insulator), or the like may be included in the support substrate 30. The thickness of the support substrate 30 is, for example, 0.2-1 mm, and any appropriate thickness other than that may be used.

Note that although not shown in the drawings, any layers may be further included in the composite substrate 100. The kinds, functions, number, combination, arrangement, and the like of such layers may be appropriately determined in accordance with purposes.

The composite substrate 100 may be manufactured in any appropriate shape. In one embodiment, the composite substrate 100 may be manufactured in the form of a so-called wafer. Further, the size of the composite substrate 100 may be set as appropriate in accordance with purposes; for example, the wafer (the substrate) has a diameter of 50 -150 mm.

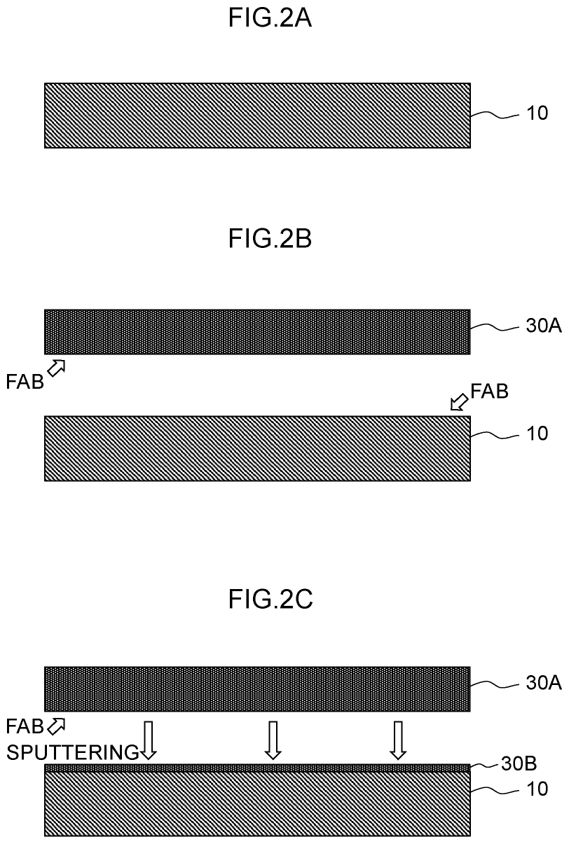

FIGS. 2A, 2B, 2C, 3A, 3B and 3C illustrate one example of a process of manufacturing a composite substrate according to the first embodiment of the present invention.

FIG. 2A illustrates a preparation step in the process of manufacturing the composite substrate 100. In this step, the functional substrate 10 made of a functional material having a predetermined thickness is prepared.

FIG. 2B illustrates an activation step in the process of manufacturing the composite substrate 100. In this step, for example, a semiconductor substrate 30A made of a semiconductor material having a predetermined thickness is prepared, and a surface of the functional substrate 10 prepared in the preparation step of FIG. 2A and a surface of the semiconductor substrate 30A are respectively irradiated with fast atomic beams (hereinafter referred to as FABs) using a noble gas such as Ar as an atomic species for a predetermined time, whereby activation treatment is performed. The irradiation time of the FAB in this case is preferably, for example, approximately 15 seconds to 30 seconds.

FIG. 2C illustrates a sputtering step in the process of manufacturing the composite substrate 100. In this step, out of the FABs respectively used for the irradiation of the functional substrate 10 and the semiconductor substrate 30A in the activation step of FIG. 2B, the FAB irradiation on the functional substrate 10 side is stopped and the FAB irradiation on the semiconductor substrate 30A side is further continued for a predetermined time. The irradiation time of the FAB in this case is preferably, for example, approximately 30-600 seconds. Thus, the semiconductor material included in the semiconductor substrate 30A is sputtered and deposited onto the surface of the functional substrate 10, so that a sputter film 30B made of a semiconductor material which is the same as that of the semiconductor substrate 30A is formed on the functional substrate 10 side. Note that as described later, a bonding layer 33 (see FIG. 3C) in the composite substrate 100 after being manufactured preferably has a thickness of 0.3 nm or more and 3 nm or less, and therefore, the sputter film 30B is preferably formed with a thickness of 0.3 nm or more and 3 nm or less in the sputtering step.

FIG. 3A illustrates a bonding step in the process of manufacturing the composite substrate 100. In this step, the functional substrate 10 on which the sputter film 30B is formed in the sputtering step of FIG. 2C and the semiconductor substrate 30A are bonded to each other. Thus, the semiconductor substrate 30A and the sputter film 30B are integrated to form the support substrate 30, and a bonded body of the functional substrate 10 and the support substrate 30 is obtained. Note that in FIG. 3A and onward, the positional relation between the functional substrate 10 and the semiconductor substrate 30A (the support substrate 30) is shown upside down as compared with FIGS. 2A-2C.

FIG. 3B illustrates the bonded body obtained after the bonding step of FIG. 3A. The semiconductor substrate 30A and the sputter film 30B are integrated as described above by the bonding step of FIG. 3A, so that the support substrate 30 including therein a bonding interface 40 thereof is formed, obtaining the bonded body as shown in FIG. 3B.

In the bonded body of FIG. 3B, a first functional layer 11 that mainly includes a crystalline substance of a functional material and a second functional layer 12 that is arranged closer to the support substrate 30 than the first functional layer 11 are formed in the functional substrate 10. The second functional layer 12 is a layer mainly including an amorphous substance of a functional material and containing noble gas atoms of Ar or the like which are emitted as the FAB in the activation step of FIG. 2B. In contrast, a first support layer 31 that is not in contact with the bonding interface 40, a second support layer 32 that is arranged closer to the functional substrate 10 than the first support layer 31 and is in contact with the bonding interface 40, and the bonding layer 33 that is arranged closer to the functional substrate 10 than the second support layer 32 and is in contact with the bonding interface 40 are formed in the support substrate 30. The second support layer 32 is a layer mainly including an amorphous substance of a semiconductor material and containing noble gas atoms of Ar or the like which are emitted as the FAB in the activation step of FIG. 2B or the sputtering step of FIG. 2C. The bonding layer 33 is a layer that corresponds to the sputter film 30B before bonding and forms a portion bonded to the functional substrate 10.

Note that the second functional layer 12 in the functional substrate 10 and the second support layer 32 and the bonding layer 33 in the support substrate 30 may contain the other atomic species that have entered these layers in the sputtering step of FIG. 2C, such as Fe atoms and Al atoms contained in a jig and a pedestal part that are used for fixing the semiconductor substrate 30A, for example. The details of these layers will be described later.

FIG. 3C illustrates a thinning step in the process of manufacturing the composite substrate 100. In this step, with respect to the bonded body shown in FIG. 3B, the functional substrate 10 is polished and thinned to a predetermined thickness. For example, the functional substrate 10 can be polished and thinned by grinding, CMP (Chemical Mechanical Polish) processing, surface flattening processing using a gas cluster ion beam, or the like.

Through the above-described steps, the composite substrate 100 having the structure shown in FIG. 1 is manufactured.

Note that an annealing step in which the bonded body is heated to predetermined temperature may be performed between the bonding step of FIG. 3A and the thinning step of FIG. 3C. The heating temperature in this case is preferably, for example, approximately 75-250 °C, more preferably 100-250 °C. Thus, the bonding strength of the functional substrate 10 can be improved.

### Second Embodiment

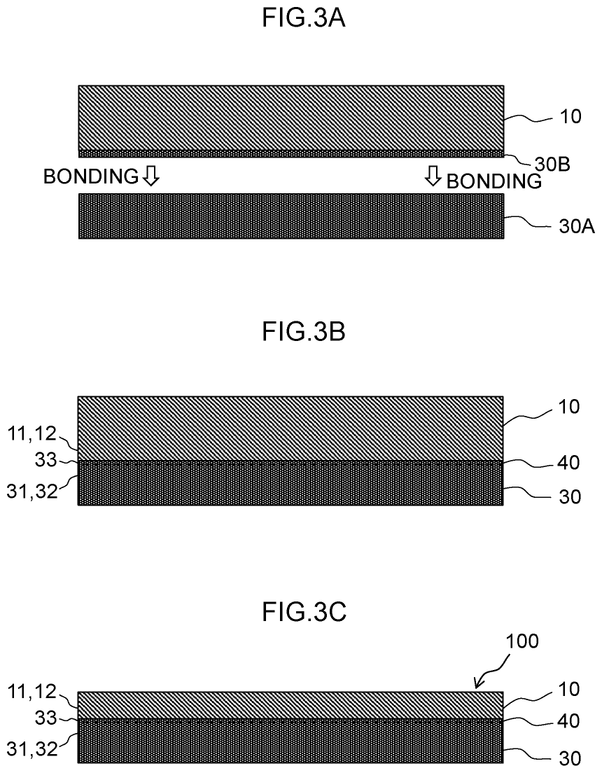

FIG. 4 is a schematic cross-sectional view showing a schematic configuration of a composite substrate according to a second embodiment of the present invention. A composite substrate 110 according to the present embodiment has a structure in which the functional substrate 10 is bonded to the support substrate 30 with an insulation layer 20 therebetween, in contrast with the composite substrate 100 of FIG. 1 which is described in the first embodiment.

The insulation layer 20 made of an insulating material is arranged between the functional substrate 10 and the support substrate 30. The insulating material included in the insulation layer 20 can be, for example, an oxide or a nitride of Si, Ta, Al, Nb, Hf, or the like, and is preferably a silicon oxide (silicon oxide). Further, a plurality of layers made of different insulating materials may be combined and included in the insulation layer 20. For example, a layer made of a silicon oxide and a layer made of a silicon oxynitride are arranged between the functional substrate 10 and the support substrate 30, so that a combination of these layers can be used as the insulation layer 20. Note that a silicon oxynitride is a substance in which oxygen atoms contained in a silicon oxide are partly replaced with nitrogen atoms.

The insulation layer 20 can be formed by any appropriate method. The formation can be performed by physical vapor deposition such as sputtering, vacuum deposition, ion beam assisted deposition (IAD), chemical vapor deposition, or an atomic layer deposition (ALD) method, for example. The formation of the insulation layer 20 can be performed, for example, at room temperature (25 °C) to 300 °C

Note that also in the present embodiment, any layer may be further included in the composite substrate 110 in a manner similar to that in the first embodiment described above. The kinds, functions, number, combination, arrangement, and the like of such a layer may be appropriately determined in accordance with purposes. Further, the composite substrate 110 can be manufactured in any appropriate shape in accordance with purposes.

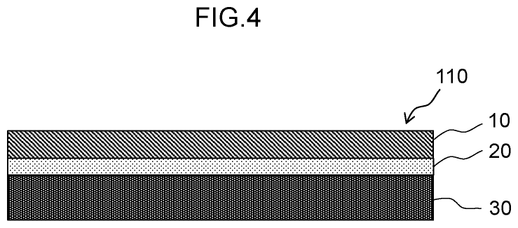

FIGS. 5A, 5B, 5C, 5D, 6A, 6B and 6C illustrate one example of a process of manufacturing a composite substrate according to the second embodiment of the present invention.

FIG. 5A illustrates a preparation step in a process of manufacturing the composite substrate 110. In this step, the functional substrate 10 having a predetermined thickness is prepared in a manner similar to that in the step of FIG. 2A which is described in the first embodiment.

FIG. 5B illustrates an insulation layer formation step in the process of manufacturing the composite substrate 110. In this step, for example, an amorphous substance of a silicon oxide having a predetermined thickness is formed on the surface of the functional substrate 10 prepared in the preparation step of FIG. 5A, whereby the insulation layer 20 is formed.

FIG. 5C illustrates an activation step in the process of manufacturing the composite substrate 110. In this step, for example, the semiconductor substrate 30A made of a semiconductor material having a predetermined thickness is prepared, and a surface of the insulation layer 20, which is formed on the functional substrate 10 in the insulation layer formation step of FIG. 5B, and the surface of the semiconductor substrate 30A are respectively irradiated with FABs using a noble gas such as Ar as an atomic species for a predetermined time in a manner similar to that in the step of FIG. 2B which is described in the first embodiment, whereby activation treatment is performed.

FIG. 5D illustrates a sputtering step in the process of manufacturing the composite substrate 110. In this step, out of the FABs respectively used for the irradiation of the functional substrate 10 and the semiconductor substrate 30A in the activation step of FIG. 5C, the FAB irradiation on the functional substrate 10 side (the insulation layer 20 side) is stopped and the FAB irradiation on the semiconductor substrate 30A side is further continued for a predetermined time, in a manner similar to that in the step of FIG. 2C which is described in the first embodiment. Thus, the semiconductor material included in the semiconductor substrate 30A is sputtered and deposited onto the surface of the insulation layer 20 formed on the functional substrate 10, so that the sputter film 30B made of a semiconductor material which is the same as that of the semiconductor substrate 30A is formed on the functional substrate 10 side (the insulation layer 20 side). Note that as in the first embodiment, the bonding layer 33 (see FIG. 6C) in the composite substrate 110 after being manufactured preferably has a thickness of 0.3 nm or more and 3 nm or less, and therefore, the sputter film 30B is preferably formed with a thickness of 0.3 nm or more and 3 nm or less in the sputtering step.

FIG. 6A illustrates a bonding step in the process of manufacturing the composite substrate 110. In this step, the functional substrate 10 in which the sputter film 30B is formed on the insulation layer 20 in the sputtering step of FIG. 5D and the semiconductor substrate 30A are bonded to each other in a manner similar to that in the step of FIG. 3A which is described in the first embodiment. Thus, the semiconductor substrate 30A and the sputter film 30B are bonded and integrated to form the support substrate 30, and a bonded body of the functional substrate 10, the insulation layer 20, and the support substrate 30 is obtained. Note that in FIG. 6A and onward, the positional relation between the functional substrate 10 and the semiconductor substrate 30A (the support substrate 30) is shown upside down as compared with FIGS. 5A-5D.

FIG. 6B illustrates the bonded body obtained after the bonding step of FIG. 6A. The semiconductor substrate 30A and the sputter film 30B are integrated as described above by the bonding step of FIG. 6A, so that the support substrate 30 including the bonding interface 40 thereof is formed, obtaining the bonded body as shown in FIG. 6B.

In the bonded body of FIG. 6B, a first insulation layer 21 that mainly includes an insulating material and a second insulation layer 22 that is arranged closer to the support substrate 30 than the first insulation layer 21 are formed in the insulation layer 20. The second insulation layer 22 is a layer mainly including an amorphous substance of an insulating material and containing noble gas atoms of Ar or the like which are emitted as the FAB in the activation step of FIG. 5C. In contrast, the first support layer 31 that is not in contact with the bonding interface 40, the second support layer 32 that is arranged closer to the functional substrate 10 than the first support layer 31 and is in contact with the bonding interface 40, and the bonding layer 33 that is arranged closer to the functional substrate 10 than the second support layer 32 and is in contact with the bonding interface 40 are formed in the support substrate 30, in a manner similar to that in the first embodiment.

FIG. 6C illustrates a thinning step in the process of manufacturing the composite substrate 110. In this step, with respect to the bonded body shown in FIG. 6B, the functional substrate 10 is polished and thinned to a predetermined thickness in a manner similar to that in the step of FIG. 3C which is described in the first embodiment.

Through the above-described steps, the composite substrate 110 having the structure shown in FIG. 4 is manufactured.

Note that also in the present embodiment, an annealing step in which the bonded body is heated to predetermined temperature may be performed between the bonding step of FIG. 6A and the thinning step of FIG. 6C, in a manner similar to that in the first embodiment.

### Third Embodiment

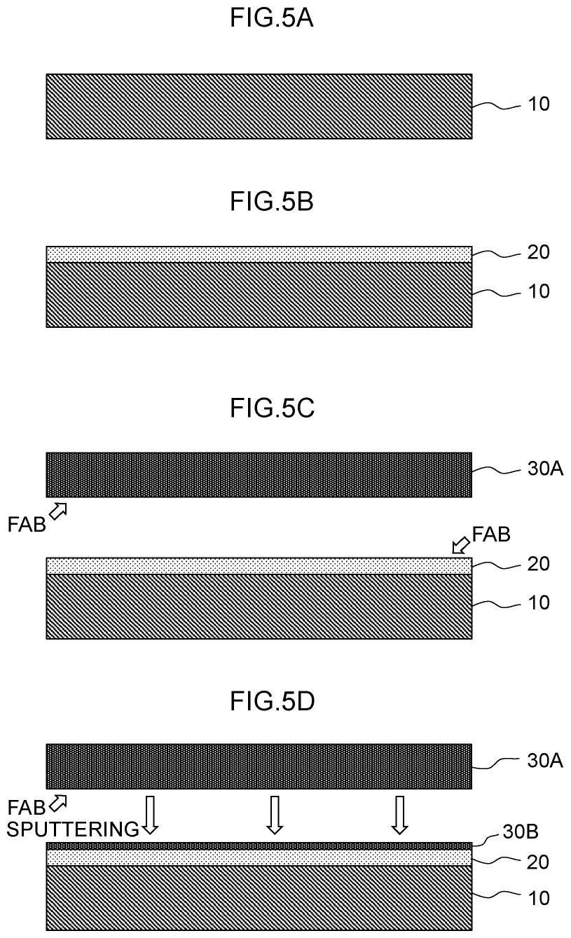

FIG. 7 is a schematic cross-sectional view showing a schematic configuration of a composite substrate according to a third embodiment of the present invention. A composite substrate 120 according to the present embodiment has a structure in which the functional substrate 10 is directly bonded to the support substrate 30, in a manner similar to that of the composite substrate 100 of FIG. 1 which is described in the first embodiment.

In the composite substrate 120 of the present embodiment, a ridge portion 50 is provided in the functional substrate 10 so that a part of the functional substrate 10 is used as an optical waveguide. The ridge portion 50 is a portion in which a level difference is provided in a part of the functional substrate 10 so that the part has a larger thickness than the other part. This ridge portion 50 is provided by performing processing (ridge processing) of forming a level difference in a part of the functional substrate 10 after the thinning step of FIG. 3C which is described in the first embodiment, for example. The ridge processing of the functional substrate 10 can be achieved by processing using laser light or dry etching such as RIE (Reactive Ion Etching), for example. Note that another step may be performed after that. Thus, the bonding interface 40 is included in the support substrate 30 also in the present embodiment.

### Fourth Embodiment

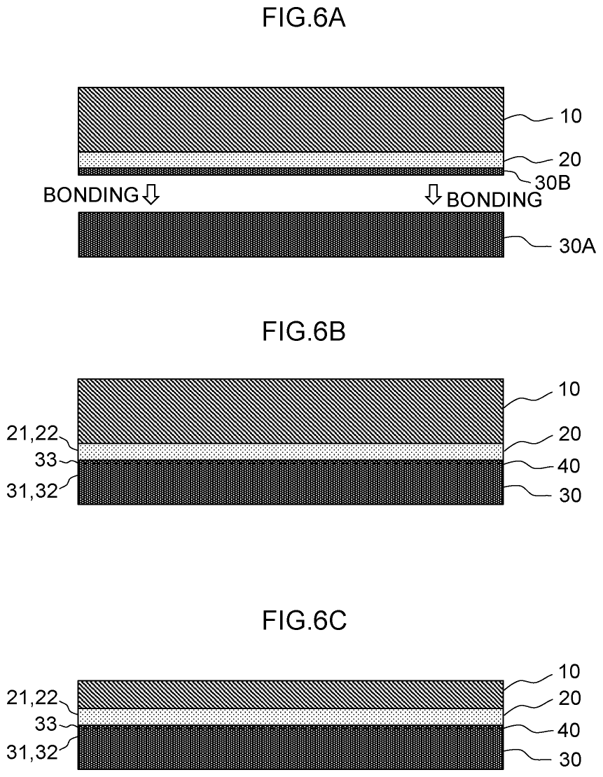

FIG. 8 is a schematic cross-sectional view showing a schematic configuration of a composite substrate according to a fourth embodiment of the present invention. A composite substrate 130 according to the present embodiment has a structure in which the functional substrate 10 is bonded to the support substrate 30 with the insulation layer 20 therebetween, in a manner similar to that of the composite substrate 110 of FIG. 4 which is described in the second embodiment.

Note that the material and the shape of the functional substrate 10 are similar to those described in the third embodiment. That is, also in the composite substrate 130 of the present embodiment, the ridge portion 50 is provided in the functional substrate 10 so that a part of the functional substrate 10 is used as an optical waveguide. This ridge portion 50 is provided by performing processing (ridge processing) of forming a level difference in the part of the functional substrate 10 after the thinning step of FIG. 6C which is described in the second embodiment, for example. Thus, the bonding interface 40 is included in the support substrate 30 also in the present embodiment.

### EXAMPLES

Examples for verifying structures of composite substrates according to the present invention will be specifically described below. Note that unless otherwise specified, the following procedure was performed at room temperature.

### Example 1

In accordance with the manufacturing process described with reference to FIGS. 2A, 2B, 2C, 3A, 3B and 3C, a bonded body was fabricated. Specifically, an LT substrate having a diameter of 4 inches and a thickness of 500 μm and a silicon substrate were prepared, and the LT substrate and the silicon substrate were used as the functional substrate 10 and the semiconductor substrate 30A, respectively.

After the surface of the functional substrate 10 and the surface of the semiconductor substrate 30A were each cleaned, the functional substrate 10 and the semiconductor substrate 30A were arranged so that, in a vacuum chamber where FAB guns were respectively placed upward and downward, these substrates were respectively positioned within the irradiation ranges of the FAB guns and the surfaces of the substrates faced each other. In this state, the vacuum chamber was evacuated to the order of 10⁻⁶ Pa, and FABs (an acceleration voltage of 1 kV and an Ar flow rate of 27 sccm) using an Ar gas were concurrently emitted from the FAB guns toward the surfaces of the functional substrate 10 and the semiconductor substrate 30A for 15 seconds.

Then, the FAB irradiation on the functional substrate 10 side was stopped, whereas the FAB irradiation on the semiconductor substrate 30A side was continued for a further 90 seconds (105 seconds in total). Note that in this case, in order to prevent change in the inner pressure of the vacuum chamber before and after the stop of the FAB irradiation on the functional substrate 10 side, the FAB irradiation from the FAB gun toward the surface of the functional substrate 10 was caused to stop while the Ar gas was kept supplied to the FAB gun on the functional substrate 10 side. As a result, the sputter film 30B was formed on the surface of the functional substrate 10.

Then, the functional substrate 10 on which the sputter film 30B was formed and the semiconductor substrate 30A were directly bonded to each other. Specifically, beam irradiation surfaces of the substrates overlapped with each other, and the application of pressure was performed with 10000 N at room temperature for two minutes to bond the substrates to each other, obtaining a bonded body. Thus, the composite substrate 100 having the structure shown in FIG. 1 was obtained.

The bonding strength of the thusly obtained composite substrate 100 was evaluated by a crack opening method and found to be 1.45 J/m², which is a sufficient bonding strength.

### Example 2

The functional substrate 10 and the semiconductor substrate 30A which were similar to those in Example 1 were arranged in a vacuum chamber and, in a state where the vacuum chamber was evacuated to the order of 10⁻⁶ Pa, FABs using an Ar gas were concurrently emitted from the FAB guns toward the surfaces of the functional substrate 10 and the semiconductor substrate 30A for 30 seconds under the conditions similar to those in Example 1.

Then, the FAB irradiation on the functional substrate 10 side was stopped, whereas the FAB irradiation on the semiconductor substrate 30A side was continued for a further 90 seconds (120 seconds in total). Note that in this case, in order to prevent change in the inner pressure of the vacuum chamber before and after the stop of the FAB irradiation on the functional substrate 10 side, the FAB irradiation from the FAB gun toward the surface of the functional substrate 10 was caused to stop while the Ar gas was kept supplied to the FAB gun on the functional substrate 10 side, in a manner similar to that in Example 1. As a result, the sputter film 30B was formed on the surface of the functional substrate 10.

Then, the functional substrate 10 on which the sputter film 30B was formed and the semiconductor substrate 30A were directly bonded to each other in a manner similar to that in Example 1; thus, the composite substrate 100 having the structure shown in FIG. 1 was obtained.

The bonding strength of the thusly obtained composite substrate 100 was evaluated by a crack opening method and found to be 1.63 J/m², which is a bonding strength improved as compared with Example 1.

### Example 3

In accordance with the manufacturing process described with reference to FIGS. 5A, 5B, 5C, 5D, 6A, 6B and 6C, a bonded body was fabricated. Specifically, the LT substrate having a diameter of 4 inches and a thickness of 500 μm and the silicon substrate were prepared, and the LT substrate and the silicon substrate were used as the functional substrate 10 and the semiconductor substrate 30A, respectively. Then, a silicon oxide was sputtered onto the functional substrate 10 to form the insulation layer 20 made of a silicon oxide film.

Afterward, in a manner similar to that in Example 1, the surface of the functional substrate 10 on which the insulation layer 20 was formed and the surface of the semiconductor substrate 30A were each cleaned, and then, the functional substrate 10 and the semiconductor substrate 30A were arranged so that, in a vacuum chamber where FAB guns were respectively placed upward and downward, these substrates were respectively positioned within the irradiation ranges of the FAB guns and a silicon oxide surface (a surface on the insulation layer 20 side) of the functional substrate 10 and the surface of the semiconductor substrate 30A faced each other. In this state, the vacuum chamber was evacuated to the order of 10⁻⁶ Pa, and FABs using an Ar gas were concurrently emitted from the FAB guns toward the surfaces of the functional substrate 10 and the semiconductor substrate 30A for 15 seconds under the conditions similar to those in Example 1.

Then, the FAB irradiation on the functional substrate 10 side was stopped, whereas the FAB irradiation on the semiconductor substrate 30A side was continued for a further 285 seconds (300 seconds in total). Note that in this case, in order to prevent change in the inner pressure of the vacuum chamber before and after the stop of the FAB irradiation on the functional substrate 10 side, the FAB irradiation from the FAB gun toward the surface of the functional substrate 10 was caused to stop while the Ar gas was kept supplied to the FAB gun on the functional substrate 10 side, in a manner similar to that in Example 1,2. As a result, the sputter film 30B was formed on the surface of the insulation layer 20 in the functional substrate 10.

Then, the functional substrate 10 on which the sputter film 30B was formed and the semiconductor substrate 30A were directly bonded to each other in a manner similar to that in Example 1,2, obtaining the composite substrate 110 having the structure shown in FIG. 4.

The bonding strength of the thusly obtained composite substrate 110 was evaluated by a crack opening method and found to be 2.01 J/m², which is a bonding strength further improved as compared with that in Example 1,2.

Note that in Examples 1-3 described above, the FAB irradiation from the FAB guns toward the functional substrate 10 and the semiconductor substrate 30A is performed for a predetermined time, and then, the FAB irradiation on the functional substrate 10 side is stopped earlier. Thus, the time needed to form the sputter film 30B can be allotted to the time for cooling the functional substrate 10, and therefore, it is possible to reduce the influence of warpage in the composite substrate 100,110 after bonding. Particularly in the case where the functional substrate 10 has a larger coefficient of thermal expansion than the semiconductor substrate 30A, the FAB irradiation on the functional substrate 10 side is stopped earlier, achieving a more increased effect with respect to a reduction of warpage after bonding.

### Comparison Example

In order to confirm the effect of the present invention, the following was performed as a comparison example: the functional substrate 10 and the semiconductor substrate 30A that were similar to those in Example 1 were arranged in a vacuum chamber and, in a state where the vacuum chamber was evacuated to the order of 10⁻⁶ Pa, only the FAB irradiation on the semiconductor substrate 30A side was performed for 90 seconds without performing the FAB irradiation on the functional substrate 10 side. The FAB irradiation on the semiconductor substrate 30A side in this case was performed under the conditions similar to those in Example 1. As a result, the sputter film 30B was formed on the surface of the insulation layer 20 in the functional substrate 10.

Then, in a manner similar to that in Example 1-3, the functional substrate 10 on which the sputter film 30B was formed and the semiconductor substrate 30A were directly bonded to each other. Thus, the composite substrate 100 having the structure shown in FIG. 1 was obtained.

The bonding strength of the thusly obtained composite substrate 100 was evaluated by a crack opening method and found to be 0.74 J/m², which is not a sufficient bonding strength.

### (Confirmation of Stacked Structure)

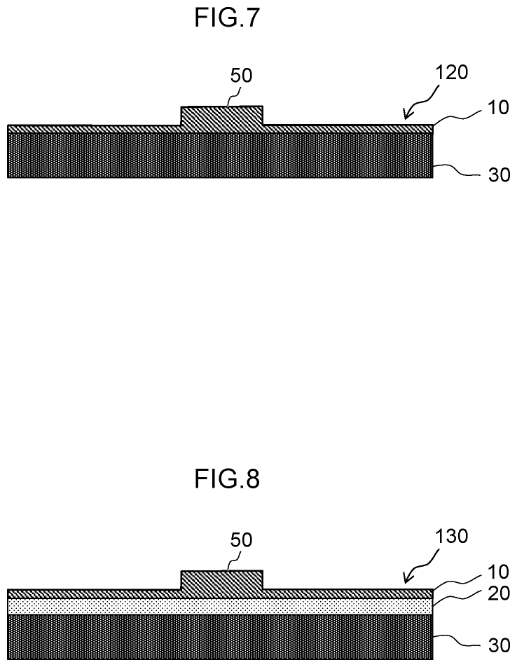

Transmission electron microscope (TEM) observation was performed on cross sections including the bonding interfaces 40 of the composite substrates 100 respectively fabricated in Example 1 and the comparison example, whereby stacked structures of the composite substrates 100 were confirmed. FIG. 9A shows an observation photograph of Example 1 and FIG. 9B shows an observation photograph of the comparison example.

From the observation photograph of Example 1 shown in FIG. 9A, it is found that two layers are formed inside the functional substrate 10. These layers are the first functional layer 11 and the second functional layer 12 in order from the side far from the support substrate 30. It is also found that three layers are formed inside the support substrate 30. These layers are the first support layer 31, the second support layer 32, and the bonding layer 33 in order from the side far from the functional substrate 10. The second functional layer 12 and the bonding layer 33 are in contact with each other, and the bonding interface 40 formed in the above-described bonding step is present between the second support layer 32 and the bonding layer 33. That is, in the bonding step, a surface of the second functional layer 12 in the semiconductor substrate 30A before bonding and a surface of the sputter film 30B formed on the functional substrate 10 before bonding are bonded to each other; thus, the sputter film 30B is turned into the bonding layer 33, so that the bonded body of the functional substrate 10 and the support substrate 30 is formed, the bonded body including the bonding interface 40 inside the support substrate 30.

From the observation photograph of FIG. 9A, it is found that the first functional layer 11 is made of a crystalline substance of LT whereas the second functional layer 12 does not have a crystal structure and includes an amorphous substance of LT. That is, in Example 1, it is found that the second functional layer 12, which corresponds to a part ranging from the surface irradiated with the FAB in the activation step to a predetermined depth in the functional substrate 10 before bonding, is formed as a layer in which LT is made amorphous, the LT being a material of the functional substrate 10.

Likewise, from the observation photograph of FIG. 9A, it is found that the first support layer 31 is made of a crystalline substance of Si whereas the second support layer 32 or the bonding layer 33 does not have a crystal structure and includes an amorphous substance of Si. That is, in Example 1, it is found that the second support layer 32, which corresponds to a part ranging from the surface irradiated with the FAB in the activation step and the sputtering step to a predetermined depth in the semiconductor substrate 30A before bonding, and the bonding layer 33, which corresponds to the sputter film 30B formed on the surface of the functional substrate 10 in the sputtering step, are each formed as a layer in which silicon is made amorphous, the silicon being a material of the support substrate 30.

In contrast, in the observation photograph of the comparison example which is shown in FIG. 9B, the functional substrate 10 includes only the first functional layer 11 having a crystal structure, and the second functional layer 12 as in Example 1 is not formed in the functional substrate 10. That is, in the comparison example, it is found that the second functional layer 12 made of an amorphous film of LT is not formed because the functional substrate 10 before bonding is not irradiated with the FAB in the activation step and thus, the bonding strength is decreased as compared with Example 1.

Note that as described above, in Example 3, the insulation layer 20 made of a silicon oxide film was formed on the surface of the functional substrate 10 before bonding, and, after the surface of the insulation layer 20 was activated, the sputter film 30B was formed and the functional substrate 10 and the semiconductor substrate 30A were caused to be bonded to each other. Hence, in the composite substrate 110 of Example 3, two layers respectively corresponding to the first functional layer 11 and the second functional layer 12 of FIG. 9A are formed in the insulation layer 20, not in the functional substrate 10. That is, in Example 3, the first insulation layer 21, which is positioned on the side far from the support substrate 30, and the second insulation layer 22, which corresponds to a part ranging from the surface irradiated with the FAB in the activation step before bonding to a predetermined depth, are formed in the insulation layer 20.

### (Structural Analysis)

EDX analysis was performed on each of the first functional layer 11, the second functional layer 12, the first support layer 31, the second support layer 32, and the bonding layer 33, which are described above, in a cross section including the bonding interface 40 of the composite substrate 100 fabricated in Example 1, whereby the structural analysis of the composite substrate 100 was performed. Likewise, EDX analysis was performed on each of the first insulation layer 21, the second insulation layer 22, the first support layer 31, the second support layer 32, and the bonding layer 33, which are described above, in a cross section including the bonding interface 40 of the composite substrate 110 fabricated in Example 3, whereby the structural analysis of the composite substrate 110 was performed.

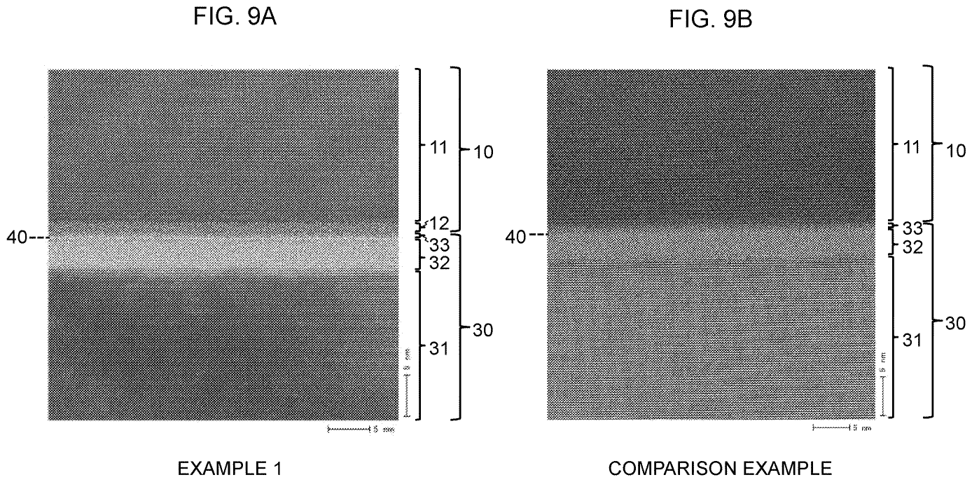

A table of FIG. 10A shows ratios of element components obtained from the EDX analysis results for each of the first functional layer 11, the second functional layer 12, the first support layer 31, the second support layer 32, and the bonding layer 33 in Example 1. For the second functional layer 12, the second support layer 32, and the bonding layer 33, the measurement results of a thickness of each of the layers are also described.

The table of FIG. 10A shows that Ar, which is a noble gas used for the FAB irradiation, is contained more in the second functional layer 12 or the second support layer 32 than in the first functional layer 11 or the first support layer 31. Further, the content thereof in the second support layer 32 is higher than the content thereof in the second functional layer 12. These results show that Ar, which is derived from the FAB emitted in each of the activation step and the sputtering step, is contained in the second functional layer 12 and the second support layer 32 and, because the second support layer 32 is irradiated with the FAB for a longer time than the second functional layer 12, more Ar is contained in the second support layer 32. Note that although the first functional layer 11 and the first support layer 31 contain a small amount of Ar in the table of FIG. 10A, there may be a case where they do not contain Ar.

In contrast, the content of Ar contained in the bonding layer 33 is lower than content thereof in the second functional layer 12 or the second support layer 32 in the table of FIG. 10A. This shows that Ar emitted as the FAB in the sputtering step is not much contained in the bonding layer 33 corresponding to the sputter film 30B.

The table of FIG. 10A also shows that Al is contained more in the bonding layer 33 than in the other layers. This is considered to be because, in the sputtering step, the FAB is emitted not only to the semiconductor substrate 30A but also partly to the jig and the pedestal part that are used for fixing the semiconductor substrate 30A, and constitutional components of these enter the bonding layer 33.

A table of FIG. 10B shows ratios of element components obtained from the EDX analysis results for each of the first insulation layer 21, the second insulation layer 22, the first support layer 31, the second support layer 32, and the bonding layer 33 in Example 3. For the second support layer 32 and the bonding layer 33, the measurement results of a thickness of each of the layers are also described.

Note that in the insulation layer 20 of Example 3, the first insulation layer 21 and the second insulation layer 22 each include an amorphous substance of a silicon oxide, unlike the functional substrate 10 of Example 1; hence, the boundary between the first insulation layer 21 and the second insulation layer 22 cannot be clearly recognized in the TEM observation photograph. Accordingly, the thickness of the second insulation layer 22 is not described in the table of FIG. 10B. However, also in the insulation layer 20 of Example 3, the second insulation layer 22 made of an amorphous substance containing much Ar like the second functional layer 12 is considered to be present in the vicinity of the bonding layer 33 (for example, in a range of approximately several nanometers from a surface of the boundary with the bonding layer 33), in a manner similar to that in the functional substrate 10 of Example 1. Thus, in the table of FIG. 10B, the EDX analysis results of the insulation layer 20 near the surface of the boundary with the bonding layer 33 are shown as the EDX analysis results of the second insulation layer 22.

Also in the table of FIG. 10B, Ar, which is a noble gas used for the FAB irradiation, is contained more in the second insulation layer 22 or the second support layer 32 than in the first insulation layer 21 or the first support layer 31 as in the table of FIG. 10A. Further, the content thereof in the second support layer 32 is higher than the content thereof in the second insulation layer 22. These results show that Ar, which is derived from the FAB emitted in each of the activation step and the sputtering step, is contained in the second insulation layer 22 and the second support layer 32 and, because the second support layer 32 is irradiated with the FAB for a longer time than the second insulation layer 22, more Ar is contained in the second support layer 32 also in Example 3, in a manner similar to that in Example 1. Note that although the first insulation layer 21 and the first support layer 31 contain a small amount of Ar in the table of FIG. 10B, there may be a case where they do not contain Ar.

In contrast, the content of Ar contained in the bonding layer 33 is lower than the content thereof in the second insulation layer 22 or the second support layer 32 in the table of FIG. 10B. This shows that Ar emitted as the FAB in the sputtering step is not much contained in the bonding layer 33 corresponding to the sputter film 30B also in Example 3, in a manner similar to that in Example 1.

Further, for similar reasons to those mentioned above, it is found that Al is contained more in the bonding layer 33 than in the other layers also in the table of FIG. 10B, as in the table of FIG. 10A.

(Relation between Bonding Layer Thickness and Bonding Strength)

The relation between the thickness of the bonding layer 33 in the support substrate 30 and the bonding strength was measured with the use of a plurality of composite substrates 110 fabricated such that, in the manufacturing parameters described in Example 3, the FAB irradiation time for the semiconductor substrate 30A in the sputtering step was varied and the other parameters were common to those in Example 3.

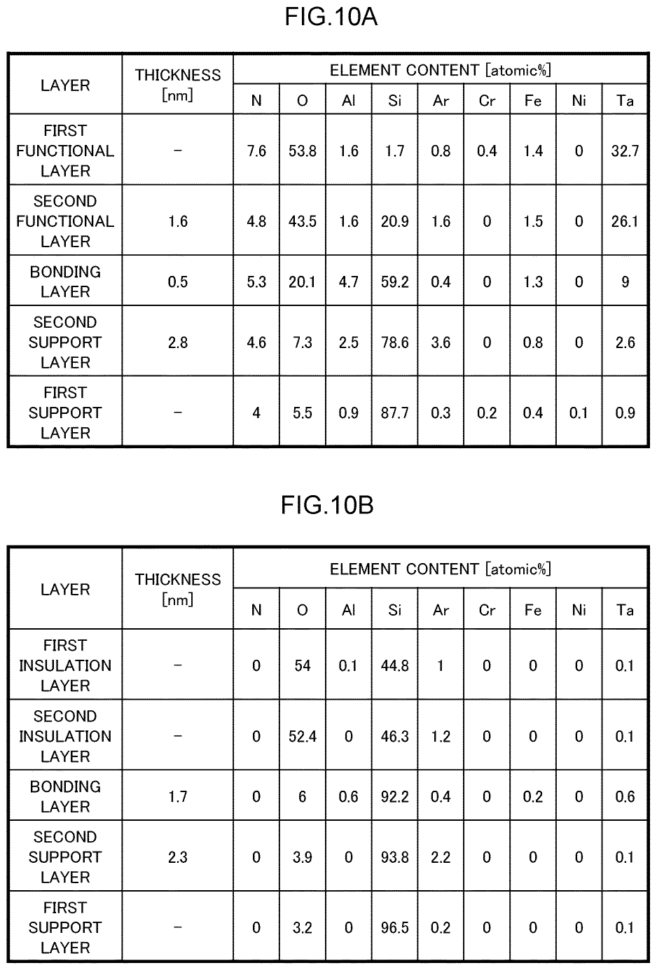

FIG. 11 is a table showing the relation between the FAB irradiation time, the thickness of the bonding layer 33, and the bonding strength in the composite substrate 110. In the table of FIG. 11, the FAB irradiation time for the functional substrate 10 and the semiconductor substrate 30A in the activation step is fixed to 15 seconds, and the FAB irradiation time for the semiconductor substrate 30A in the sputtering step is varied between 50 seconds, 90 seconds, 195 seconds, 285 seconds, and 585 seconds; for these cases, the table shows a total time for the FAB irradiation of the semiconductor substrate 30A in the activation step and also the sputtering step, and the thickness of the bonding layer 33 and the bonding strength in each of the fabricated composite substrates 110. Note that the case where the FAB irradiation time in the sputtering step is 285 seconds corresponds to Example 3 described above.

The table of FIG. 11 shows that, when the thickness of the bonding layer 33 is 0.3 nm or more, the bonding strength is 1 J/m² or more, which is a sufficient bonding strength. That is, in the composite substrate described in Patent Literature 1 described above, a thickness of at least approximately 2 nm had been needed for the bonding layer to achieve a bonding strength of 1 J/m² or more, whereas the composite substrate 110 to which the present invention is applied can achieve a bonding strength that is approximately equal to or higher than that in the composite substrate described in Patent Literature 1 as long as the thickness of the bonding layer 33 is 0.3 nm or more. The same applies to the other composite substrate 100,120,130.

Note that in terms of reducing the manufacture time in the sputtering step, reducing the size of products, and the like, the thickness of the bonding layer 33 is preferably as thin as possible as long as a sufficient bonding strength is achieved in the manufactured composite substrate 100-130. For example, when a maximum thickness of the bonding layer 33 is 3 nm, the thickness of the bonding layer 33 in the composite substrate 100-130 can be 0.3 nm or more and 3 nm or less according to the above-described results.

(Relation between FAB Irradiation Time in Activation Step and Bonding Strength)

The relation between the FAB irradiation time in the activation step and the bonding strength was measured with the use of a plurality of composite substrates 100 fabricated such that, in the manufacturing parameters described in Example 1,2, the FAB irradiation time for the functional substrate 10 in the activation step was varied and the other parameters were common to those in Example 1,2.

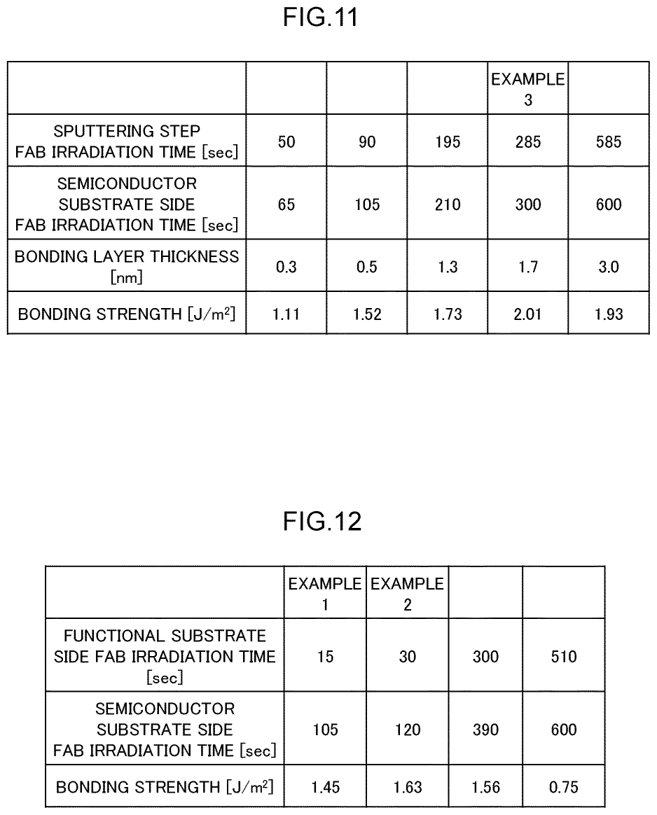

FIG. 12 is a table showing the relation between the FAB irradiation time for the functional substrate 10 and the semiconductor substrate 30A and the bonding strength in the composite substrate 100. In the table of FIG. 12, the FAB irradiation time for the functional substrate 10 and the semiconductor substrate 30A in the activation step is varied between 15 seconds, 30 seconds, 300 seconds, and 510 seconds, and the FAB irradiation time for the semiconductor substrate 30A in the sputtering step is fixed to 90 seconds; for these cases, the table shows a total time for the FAB irradiation of the semiconductor substrate 30A in the activation step and also the sputtering step and the bonding strength in each of the fabricated composite substrates 100. Note that the cases where the FAB irradiation time in the sputtering step is 15 seconds and 30 seconds correspond to Examples 1 and 2, respectively, which are described above.

The table of FIG. 12 shows that, when the FAB irradiation time in the activation step is 300 seconds or less, the bonding strength is 1 J/m² or more, which is a sufficient bonding strength; whereas, when the FAB irradiation time in the activation step exceeds 300 seconds, the bonding strength is decreased. This is considered to be because the surface roughness of the functional substrate 10 is increased as the FAB irradiation time for the functional substrate 10 in the activation step becomes longer and, when the surface roughness is above a certain level, the bonding strength is decreased.

Note that the values of the FAB irradiation time, the thickness of the bonding layer 33, and the bonding strength that are given in the table of FIGS. 11,12 are merely examples. These values may be changed in accordance with the kinds of the functional material and the semiconductor material that are used in the functional substrate 10 and the semiconductor substrate 30A, the voltage and the current of the FAB, the flow rate of the noble gas, and the like. Hence, for example, instead of controlling the FAB irradiation time, the voltage and the current of the FAB, the flow rate of the noble gas, and the like can be controlled to form the bonding layer 33 with a desired thickness.

According to the embodiments of the present invention described above, the following operations and effects can be achieved.
(1) Composite substrates 100-130 each include: a functional substrate 10 made of a functional material; and a support substrate 30 made of a semiconductor material and bonded to the functional substrate 10 to support the functional substrate 10. The functional substrate 10 includes a first layer (a first functional layer 11 or a first insulation layer 21) and a second layer (a second functional layer 12 or a second insulation layer 22) that is arranged closer to the support substrate 30 than the first layer and is made of an amorphous substance containing a noble gas. The support substrate 30 includes: a first support layer 31; a second support layer 32 that is arranged closer to the functional substrate 10 than the first support layer 31 and is made of an amorphous substance of the semiconductor material containing the noble gas; and a bonding layer 33 that is in contact with the functional substrate 10 and is made of an amorphous substance of the semiconductor material. This allows provision of the composite substrates 100-130 capable of achieving a sufficient bonding strength even when the bonding layer 33 has a small thickness, in the composite substrates 100-130 in which the functional substrate 10 and the support substrate 30 are bonded to each other with the bonding layer 33 therebetween.
(2) In the composite substrates 100 and 120, the functional substrate 10 includes: a first functional layer 11 that is made of a crystalline substance of the functional material; and a second functional layer 12 that includes an amorphous substance of the functional material and is in contact with the bonding layer 33. In this configuration, the first layer is the first functional layer 11 and the second layer is the second functional layer 12. This allows provision of the composite substrates 100 and 120 capable of achieving a sufficient bonding strength even when the functional substrate 10 and the support substrate 30 are directly bonded to each other without an insulation layer 20 therebetween.
(3) In the composite substrates 110 and 130, the functional substrate 10 is bonded to the support substrate 30 with an insulation layer 20 therebetween, the insulation layer 20 being made of an insulating material, and the insulation layer 20 includes: a first insulation layer 21 that is made of the insulating material; and a second insulation layer 22 that includes an amorphous substance of the insulating material and is in contact with the bonding layer 33. In this configuration, the first layer is the first insulation layer 21 and the second layer is the second insulation layer 22. This allows provision of the composite substrates 110 and 130 capable of achieving a sufficient bonding strength even when the functional substrate 10 and the support substrate 30 are bonded to each other with the insulation layer 20 therebetween.
(4) The bonding layer 33 in the composite substrates 100-130 preferably has a thickness of 0.3 nm or more and 3 nm or less. This allows the manufacture time and the size of products to be reduced while a sufficient bonding strength is maintained.
(5) As shown in FIGS. 10A and 10B, the bonding layer 33 contains the noble gas such as Ar, and the content of the noble gas in the bonding layer 33 is lower than the content of the noble gas in the second support layer 32. Further, the bonding layer 33 may contain a metal element such as Al. This allows fabrication of the composite substrates 100-130 such that the functional substrate 10 and the semiconductor substrate 30A are bonded to each other using, as the bonding layer 33, the sputter film 30B which is formed on the surface of the functional substrate 10 by the FAB irradiation of the surface of the semiconductor substrate 30A, and the semiconductor substrate 30A is used as the support substrate 30.
(6) As shown in FIG. 10A, the first functional layer 11 contains the noble gas such as Ar or does not contain the noble gas, and the content of the noble gas in the first functional layer 11 when the first functional layer 11 contains the noble gas is lower than the content of the noble gas in the second functional layer 12. Further, the content of the noble gas in the second functional layer 12 is lower than the content of the noble gas in the second support layer 32. This allows fabrication of the composite substrates 100,120 such that the FAB irradiation is performed on the surface of the functional substrate 10 before bonding to activate the surface of the functional substrate 10, and then, the functional substrate 10 and the semiconductor substrate 30A are bonded to each other.
(7) As shown in FIG. 10B, the first insulation layer 21 contains the noble gas such as Ar or does not contain the noble gas, and the content of the noble gas in the first insulation layer 21 when the first insulation layer 21 contains the noble gas is lower than the content of the noble gas in the second insulation layer 22. Further, the content of the noble gas in the second insulation layer 22 is lower than the content of the noble gas in the second support layer 32. This allows fabrication of the composite substrates 110,130 such that the FAB irradiation is performed on the surface of the functional substrate 10 before bonding, on which the insulation layer 20 is formed, to activate the surface of the insulation layer 20, and then, the insulation layer 20 and the semiconductor substrate 30A are bonded to each other.
(8) As shown in FIGS. 10A and 10B, the first support layer 31 contains the noble gas such as Ar or does not contain the noble gas, and the content of the noble gas in the first support layer 31 when the first support layer 31 contains the noble gas is lower than the content of the noble gas in the second support layer 32. This allows fabrication of the composite substrates 100-130 such that the FAB irradiation of the surface of the semiconductor substrate 30A is performed, and then, the functional substrate 10 and the semiconductor substrate 30A are bonded to each other, and the semiconductor substrate 30A is used as the support substrate 30.
(9) A method of manufacturing composite substrates 100 and 120 each including a functional substrate 10 made of a functional material and a support substrate 30 including a semiconductor material and supporting the functional substrate 10 includes: an activation step (FIG. 2B) of performing irradiation with an FAB on each of a surface of the functional substrate 10 and a surface of a semiconductor substrate 30A made of the semiconductor material so that at least portions of times for respectively irradiating the surfaces overlap with each other; a sputtering step (FIG. 2C) of sputtering the semiconductor material onto the surface of the functional substrate 10 by continuing the irradiation of the surface of the semiconductor substrate 30A with the FAB after stopping the irradiation of the surface of the functional substrate 10 with the FAB, the sputtering step being performed subsequent to the activation step; and a bonding step (FIG. 3A) of bonding the functional substrate 10, on which the semiconductor material is sputtered in the sputtering step, and the semiconductor substrate 30A to each other to obtain a bonded body. This allows fabrication of the composite substrates 100 and 120 such that the support substrate 30 is formed by integrating the semiconductor substrate 30A and the sputter film 30B.
(10) A method of manufacturing composite substrates 110 and 130 each including a functional substrate 10 made of a functional material and a support substrate 30 including a semiconductor material and supporting the functional substrate 10 includes: an insulation layer formation step (FIG. 5B) of forming, on a surface of the functional substrate 10, an insulation layer 20 made of an insulating material; an activation step (FIG. 5C) of performing irradiation with a FAB on each of a surface of the insulation layer 20 and a surface of a semiconductor substrate 30A made of the semiconductor material so that at least portions of times for respectively irradiating the surfaces overlap with each other; a sputtering step (FIG. 5D) of sputtering the semiconductor material onto the surface of the insulation layer 20 by continuing the irradiation of the surface of the semiconductor substrate 30A with the FAB after stopping the irradiation of the surface of the insulation layer 20 with the FAB, the sputtering step being performed subsequent to the activation step; and a bonding step (FIG. 6A) of bonding the functional substrate 10 and the semiconductor substrate 30A to each other with the insulation layer 20, on which the semiconductor material is sputtered in the sputtering step, therebetween to obtain a bonded body. This allows fabrication of the composite substrates 110 and 130 such that the functional substrate 10 and the support substrate 30 are bonded to each other with the insulation layer 20 therebetween.
(11) In the sputtering step of FIGS. 2C and 5D, the sputter film 30B is preferably formed with a thickness of 0.3 nm or more and 3 nm or less. This allows fabrication of the composite substrates 100-130 capable of reducing the manufacture time and reducing the size of products while a sufficient bonding strength is maintained.
(12) The functional substrate 10 and the semiconductor substrate 30A may be arranged in a vacuum chamber in which a first FAB gun and a second FAB gun are placed. In the activation step of FIGS. 2B and 5C, a noble gas such as Ar may be supplied to each of the first FAB gun and the second FAB gun, the surface of the functional substrate 10 or the insulation layer 20 may be irradiated with the FAB using the noble gas from the first FAB gun, and further, the surface of the semiconductor substrate 30A may be irradiated with the FAB using the noble gas from the second FAB gun. Further, in the sputtering step of FIGS. 2C and 5D, the irradiation with the FAB from the first FAB gun toward the surface of the functional substrate 10 or the insulation layer 20 may be stopped while the noble gas is kept supplied to the first FAB gun. This allows the activation step to be appropriately performed on the functional substrate 10 and the semiconductor substrate 30A and allows the sputtering step to be appropriately performed on the semiconductor substrate 30A, enabling fabrication of the composite substrates 100-130.

Note that in each of the above-described embodiments of the present invention, the FAB irradiation from the first FAB gun toward the surface of the functional substrate 10 or the insulation layer 20 and the FAB irradiation from the second FAB gun toward the surface of the semiconductor substrate 30A are concurrently performed. Thus, impurities of an oxide film or the like formed on the surface of the semiconductor substrate 30A can be prevented from being deposited onto the surface of the functional substrate 10 or the insulation layer 20. However, the present invention is not limited to this. For example, a method may be used in which the FAB irradiation on the functional substrate 10 side from the first FAB gun is started earlier, then, after a predetermined time after that, the FAB irradiation on the semiconductor substrate 30A side from the second FAB gun is started, and then, the FAB irradiation on the functional substrate 10 side is stopped earlier. This also achieves an effect similar to the effect described above.

Note that the present invention is not limited to the above-described embodiments and can be implemented using any constituent element without departing from the gist thereof.

The above-described embodiments and modified examples are merely examples, and the present invention is not limited to these within a range that does not impair the characteristics of the invention. Various embodiments and modified examples have been described above, but the present invention is not limited to these. Other modes that are considered to fall within the range of the technical concept of the present invention are also included within the scope of the present invention.

What is claimed is:

1. A composite substrate comprising:
a functional substrate made of a functional material; and
a support substrate made of a semiconductor material and bonded to the functional substrate to support the functional substrate, wherein
the functional substrate includes a first layer and a second layer arranged closer to the support substrate than the first layer and made of an amorphous substance containing a noble gas,
the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material,
the functional substrate includes: a first functional layer that is made of a crystalline substance of the functional material; and a second functional layer that includes an amorphous substance of the functional material and is in contact with the bonding layer,
the first layer is the first functional layer,
the second layer is the second functional layer,
the bonding layer contains the noble gas, and
a content of the noble gas in the bonding layer is lower than a content of the noble gas in the second support layer.

2. A composite substrate comprising:
a functional substrate made of a functional material; and
a support substrate made of a semiconductor material and bonded to the functional substrate to support the functional substrate, wherein
the functional substrate includes a first layer and a second layer arranged closer to the support substrate than the first layer and made of an amorphous substance containing a noble gas,
the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material,
the functional substrate is bonded to the support substrate with an insulation layer therebetween, the insulation layer being made of an insulating material,
the insulation layer includes: a first insulation layer made of the insulating material; and a second insulation layer that includes an amorphous substance of the insulating material and is in contact with the bonding layer,
the first layer is the first insulation layer,
the second layer is the second insulation layer,
the bonding layer contains the noble gas, and
a content of the noble gas in the bonding layer is lower than a content of the noble gas in the second support layer.

3. A composite substrate comprising:
a functional substrate made of a functional material; and
a support substrate made of a semiconductor material and bonded to the functional substrate to support the functional substrate, wherein
the functional substrate includes a first layer and a second layer arranged closer to the support substrate than the first layer and made of an amorphous substance containing a noble gas,
the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material,
the functional substrate includes: a first functional layer that is made of a crystalline substance of the functional material; and a second functional layer that includes an amorphous substance of the functional material and is in contact with the bonding layer,
the first layer is the first functional layer,
the second layer is the second functional layer,
the first functional layer contains the noble gas or does not contain the noble gas,
a content of the noble gas in the first functional layer when the first functional layer contains the noble gas is lower than a content of the noble gas in the second functional layer, and
the content of the noble gas in the second functional layer is lower than a content of the noble gas in the second support layer.

4. A composite substrate comprising:
a functional substrate made of a functional material; and
a support substrate made of a semiconductor material and bonded to the functional substrate to support the functional substrate, wherein
the functional substrate includes a first layer and a second layer arranged closer to the support substrate than the first layer and made of an amorphous substance containing a noble gas,
the support substrate includes: a first support layer; a second support layer that is arranged closer to the functional substrate than the first support layer and is made of an amorphous substance of the semiconductor material containing the noble gas; and a bonding layer that is in contact with the functional substrate and is made of an amorphous substance of the semiconductor material,
the functional substrate is bonded to the support substrate with an insulation layer therebetween, the insulation layer being made of an insulating material,
the insulation layer includes: a first insulation layer made of the insulating material; and a second insulation layer that includes an amorphous substance of the insulating material and is in contact with the bonding layer,
the first layer is the first insulation layer,
the second layer is the second insulation layer,
the first functional layer contains the noble gas or does not contain the noble gas,
a content of the noble gas in the first functional layer when the first functional layer contains the noble gas is lower than a content of the noble gas in the second functional layer, and
the content of the noble gas in the second functional layer is lower than a content of the noble gas in the second support layer.

5. The composite substrate according to claim 1, wherein
the bonding layer has a thickness of 0.3 nm or more and 3 nm or less.

6. The composite substrate according to claim 1, wherein
the bonding layer contains a metal element.

7. The composite substrate according to claim 1, wherein
the first functional layer contains the noble gas or does not contain the noble gas, and
a content of the noble gas in the first functional layer when the first functional layer contains the noble gas is lower than a content of the noble gas in the second functional layer.

8. The composite substrate according to claim 7, wherein
the content of the noble gas in the second functional layer is lower than a content of the noble gas in the second support layer.

9. The composite substrate according to claim 1, wherein
the first support layer contains the noble gas or does not contain the noble gas, and
a content of the noble gas in the first support layer when the first support layer contains the noble gas is lower than a content of the noble gas in the second support layer.

10. The composite substrate according to claim 2, wherein
the bonding layer has a thickness of 0.3 nm or more and 3 nm or less.

11. The composite substrate according to claim 2, wherein
the bonding layer contains a metal element.

12. The composite substrate according to claim 2, wherein
the first insulation layer contains the noble gas or does not contain the noble gas, and
a content of the noble gas in the first insulation layer when the first insulation layer contains the noble gas is lower than a content of the noble gas in the second insulation layer.

13. The composite substrate according to claim 12, wherein
the content of the noble gas in the second insulation layer is lower than a content of the noble gas in the second support layer.

14. The composite substrate according to claim 2, wherein
the first support layer contains the noble gas or does not contain the noble gas, and
a content of the noble gas in the first support layer when the first support layer contains the noble gas is lower than a content of the noble gas in the second support layer.

15. The composite substrate according to claim 3, wherein
the bonding layer has a thickness of 0.3 nm or more and 3 nm or less.

16. The composite substrate according to claim 3, wherein
the bonding layer contains a metal element.

17. The composite substrate according to claim 3, wherein
the first support layer contains the noble gas or does not contain the noble gas, and
a content of the noble gas in the first support layer when the first support layer contains the noble gas is lower than a content of the noble gas in the second support layer.

18. The composite substrate according to claim 4, wherein
the bonding layer has a thickness of 0.3 nm or more and 3 nm or less.

19. The composite substrate according to claim 4, wherein
the bonding layer contains a metal element.

20. The composite substrate according to claim 4, wherein
the first support layer contains the noble gas or does not contain the noble gas, and
a content of the noble gas in the first support layer when the first support layer contains the noble gas is lower than a content of the noble gas in the second support layer.

21. A method of manufacturing a composite substrate including a functional substrate made of a functional material and a support substrate including a semiconductor material and supporting the functional substrate, the method comprising:
an activation step of performing irradiation with a fast atom beam on each of a surface of the functional substrate and a surface of a semiconductor substrate made of the semiconductor material so that at least portions of times for respectively irradiating the surfaces overlap with each other;
a sputtering step of sputtering the semiconductor material onto the surface of the functional substrate by continuing the irradiation of the surface of the semiconductor substrate with the fast atom beam after stopping the irradiation of the surface of the functional substrate with the fast atom beam, the sputtering step being performed subsequent to the activation step; and
a bonding step of bonding the functional substrate, on which the semiconductor material is sputtered in the sputtering step, and the semiconductor substrate to each other to obtain a bonded body.

22. A method of manufacturing a composite substrate including a functional substrate made of a functional material and a support substrate including a semiconductor material and supporting the functional substrate, the method comprising:
an insulation layer formation step of forming, on a surface of the functional substrate, an insulation layer made of an insulating material;
an activation step of performing irradiation with a fast atom beam on each of a surface of the insulation layer and a surface of a semiconductor substrate made of the semiconductor material so that at least portions of times for respectively irradiating the surfaces overlap with each other;
a sputtering step of sputtering the semiconductor material onto the surface of the insulation layer by continuing the irradiation of the surface of the semiconductor substrate with the fast atom beam after stopping the irradiation of the surface of the insulation layer with the fast atom beam, the sputtering step being performed subsequent to the activation step; and
a bonding step of bonding the functional substrate and the semiconductor substrate to each other with the insulation layer, on which the semiconductor material is sputtered in the sputtering step, therebetween to obtain a bonded body.

23. The method of manufacturing the composite substrate according to claim 21, wherein
in the sputtering step, a sputter film made of an amorphous substance of the sputtered semiconductor material is formed with a thickness of 0.3 nm or more and 3 nm or less on the surface of the functional substrate or the insulation layer.

24. The method of manufacturing the composite substrate according to claim 21, wherein
the functional substrate and the semiconductor substrate are arranged in a vacuum chamber in which a first fast atom beam gun and a second fast atom beam gun are placed,
in the activation step, a noble gas is supplied to each of the first fast atom beam gun and the second fast atom beam gun, the surface of the functional substrate or the insulation layer is irradiated with the fast atom beam using the noble gas from the first fast atom beam gun, and further, the surface of the semiconductor substrate is irradiated with the fast atom beam using the noble gas from the second fast atom beam gun, and
in the sputtering step, the irradiation with the fast atom beam from the first fast atom beam gun toward the surface of the functional substrate or the insulation layer is stopped while the noble gas is kept supplied to the first fast atom beam gun.

25. The method of manufacturing the composite substrate according to claim 24, wherein
in the activation step, the irradiation with the fast atom beam from the first fast atom beam gun toward the surface of the functional substrate or the insulation layer and the irradiation with the fast atom beam from the second fast atom beam gun toward the surface of the semiconductor substrate are concurrently performed.

26. The method of manufacturing the composite substrate according to claim 22, wherein
in the sputtering step, a sputter film made of an amorphous substance of the sputtered semiconductor material is formed with a thickness of 0.3 nm or more and 3 nm or less on the surface of the functional substrate or the insulation layer.

27. The method of manufacturing the composite substrate according to claim 22, wherein
the functional substrate and the semiconductor substrate are arranged in a vacuum chamber in which a first fast atom beam gun and a second fast atom beam gun are placed,
in the activation step, a noble gas is supplied to each of the first fast atom beam gun and the second fast atom beam gun, the surface of the functional substrate or the insulation layer is irradiated with the fast atom beam using the noble gas from the first fast atom beam gun, and further, the surface of the semiconductor substrate is irradiated with the fast atom beam using the noble gas from the second fast atom beam gun, and
in the sputtering step, the irradiation with the fast atom beam from the first fast atom beam gun toward the surface of the functional substrate or the insulation layer is stopped while the noble gas is kept supplied to the first fast atom beam gun.

28. The method of manufacturing the composite substrate according to claim 27, wherein
in the activation step, the irradiation with the fast atom beam from the first fast atom beam gun toward the surface of the functional substrate or the insulation layer and the irradiation with the fast atom beam from the second fast atom beam gun toward the surface of the semiconductor substrate are concurrently performed.
